(19) United States
(12) Patent Application Publication
(10) Pub. No.: US 2025/0227951 A1
(43) Pub. Date: Jul. 10, 2025

(54) SEMICONDUCTOR DEVICE AND METHOD OF MANUFACTURING THE SAME

(71) Applicant: TAIWAN SEMICONDUCTOR MANUFACTURING COMPANY LTD., HSINCHU (TW)

(72) Inventors: HSING YU CHEN, HSINCHU CITY (TW); KAOCHAO CHEN, HSINCHU CITY (TW); CHIA-CHENG HO, HSINCHU CITY (TW)

(21) Appl. No.: 18/406,246

(22) Filed: Jan. 8, 2024

(51) Int. Cl. H01L 29/78; H01L 29/10; H01L 29/66

(52) U.S. Cl. CPC H10D 30/65; H10D 30/0281; H10D 62/393

(57) ABSTRACT

A semiconductor device and a method of manufacturing the same are provided. The semiconductor device includes a substrate, a plurality of gate stack structures, and an ILD. The substrate includes an active region. The gate stack structures are disposed on the active region of the substrate. The isolation structure is embedded within the substrate and surrounding the active region. The ILD covers the gate stack structures. The ILD includes a first protruding portion protruding toward the isolation structure.

### BACKGROUND

Technological advances in semiconductor integrated circuit (IC) materials, design, processing, and manufacturing have enabled the continual reduction in size of IC devices, where each generation has smaller and more complex circuits than the previous generation.

As semiconductor circuits composed of devices such as metal-oxide-semiconductor field-effect transistors (MOSFETs) are adapted for high voltage applications, such as in lateral diffusion metal-oxide-semiconductor (LDMOS) devices, problems arise with respect to decreasing voltage performance amidst the continued downscaling in advanced technologies. To improve the shift of threshold voltage, a new semiconductor device is required.

### BRIEF DESCRIPTION OF THE DRAWINGS

Aspects of the embodiments of the present disclosure are best understood from the following detailed description when read with the accompanying figures. It should be noted that, in accordance with the standard practice in the industry, various structures are not drawn to scale. In fact, the dimensions of the various structures may be arbitrarily increased or reduced for clarity of discussion.

FIG. 1A illustrates a top view of a semiconductor device, in accordance with some embodiments of the present disclosure.

FIG. 1B illustrates a cross-sectional view along line A-A′ of the semiconductor device as shown in FIG. 1A, in accordance with some embodiments of the present disclosure.

FIG. 2 illustrates a cross-sectional view of a semiconductor device, in accordance with some embodiments of the present disclosure.

FIG. 3A illustrates a top view of a semiconductor device, in accordance with some embodiments of the present disclosure.

FIG. 3B illustrates a cross-sectional view along line B-B′ of the semiconductor device as shown in FIG. 1A, in accordance with some embodiments of the present disclosure.

FIG. 4, FIG. 5A, FIG. 5B, FIG. 6A, FIG. 6B, FIG. 7, FIG. 8, FIG. 9, FIG. 10, and FIG. 11 illustrate various stages of manufacturing a semiconductor device, in accordance with some embodiments of the present disclosure.

FIG. 12 is a flow chart illustrating a method for manufacturing a semiconductor device according to various aspects of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, although terms such as “first,” “second” and “third” describe various elements, components, regions, layers and/or sections, these elements, components, regions, layers and/or sections should not be limited by these terms. These terms may only be used to distinguish one element, component, region, layer or section from another. Terms such as “first,” “second” and “third” when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the terms “substantially,” “approximately” and “about” generally mean within a value or range that can be contemplated by people having ordinary skill in the art. Alternatively, the terms “substantially,” “approximately” and “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and the attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

In some embodiments, semiconductor devices 1a, 1b, and 1c are provided. Each of the semiconductor devices 1a, 1b, and 1c can be a high voltage semiconductor device. Each of the semiconductor devices 1a, 1b, and 1c can be an n type or a p type high-voltage device. In some embodiments, each of the semiconductor devices 1a, 1b, and 1c can be referred to as a laterally-diffused MOS (LDMOS) transistor device, a high-voltage laterally-diffused MOS (HV LDMOS) transistor device, a high-voltage extended-drain MOS (HV EDMOS) transistor device, or any other device. In some embodiments of the disclosure, at the stage to define the location of body regions, the mask defines openings over an isolation structure, which thereby reduces the variations of dopant concentration, dopant profile, and/or dopant distribution of the body regions between devices of different quantities of gate stack structures. As a result, the shift of the threshold voltage can be improved.

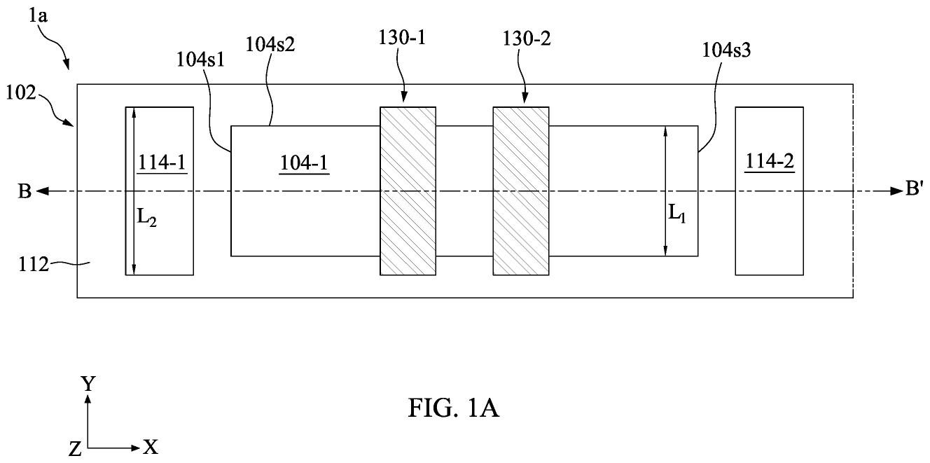

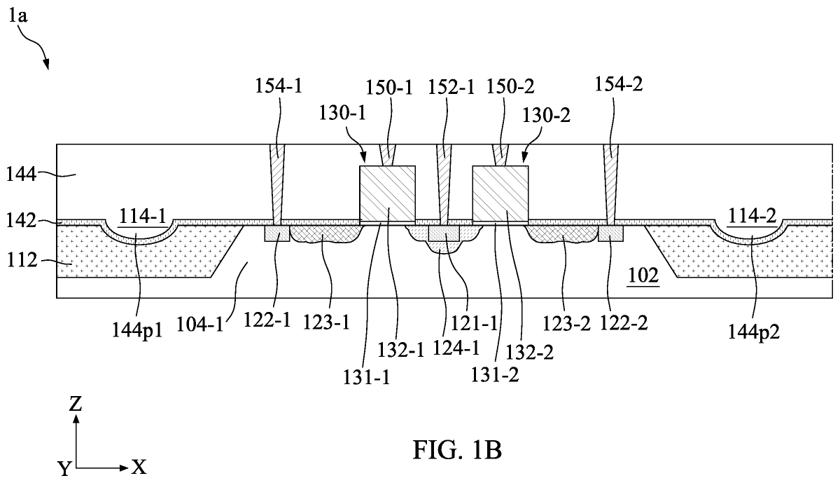

FIG. 1A and FIG. 1B illustrates the semiconductor device 1a, in accordance with some embodiments of the present disclosure, wherein FIG. 1A is a top view, and FIG. 1B is a cross-sectional view taken along line A-A′ of FIG. 1A. It should be noted that some features, elements, and/or components are omitted from FIG. 1A for brevity.

Referring to FIG. 1A, the semiconductor device 1a includes a substrate 102, an isolation structure 112, and gate stack structures 130-1 and 130-2. In some embodiments, the substrate 102 defines an active region 104-1 surrounded by the isolation structure 112. The active region 104-1 is configured to define a two-finger gate stack structure system. Each of the gate stack structures 130-1 and 130-2 extends along the Y-direction and is arranged along the X-direction.

Referring to FIG. 1B, the substrate 102 may be a semiconductor substrate, such as a bulk semiconductor, a semiconductor-on-insulator (SOI) substrate, or the like, which may be doped (e.g., with a p type or an n type dopant) or undoped. The substrate 102 can include an elementary semiconductor including silicon or germanium in a single crystal form, a polycrystalline form, or an amorphous form; a compound semiconductor material including at least one of silicon carbide, gallium arsenide, gallium phosphide, indium phosphide, indium arsenide, and indium antimonide; an alloy semiconductor material including at least one of SiGe, GaAsP, AlInAs, AlGaAs, GaInAs, GainP, and GaInAsP; any other suitable material; or a combination thereof. In some embodiments, the alloy semiconductor substrate may be a SiGe alloy with a gradient Ge feature in which the Si and Ge composition changes from one ratio at one location to another ratio at another location of the gradient SiGe feature. In another embodiment, the SiGe alloy is formed over a silicon substrate. In some embodiments, a SiGe alloy can be mechanically strained by another material in contact with the SiGe alloy. In some embodiments, the substrate 102 may have a multilayer structure, or the substrate 102 may include a multilayer compound semiconductor structure.

The active region 104-1 is surrounded by the isolation structure 112. In some embodiments, the active region 104-1 is a region on which gate stack structures, source/drain features, and/or other features are disposed.

In some embodiments, the isolation structure 112 is disposed within the substrate 102. In some embodiments, the isolation structure 112 is a shallow trench isolation (STI). In other embodiments, the isolation structure 112 includes a structure of a local oxidization of silicon (LOCOS) structure, or any other suitable isolation structure.

In some embodiments, the isolation structure 112 defines recesses 114-1 and 114-2. In some embodiments, each of the recesses 114-1 and 114-2 is recessed from an upper surface of the isolation structure 112. For example, each of the recesses 114-1 and 114-2 has a bowl-shaped profile in a cross-sectional view. Each of the recesses 114-1 and 114-2 is formed by an etching technique configured to remove a gate dielectric material, which will be described in detail later.

Referring back to FIG. 1A, each of the recesses 114-1 and 114-2 extends along the Y-direction. The recess 114-1 is disposed at or abuts a side 104s1 of the active region 104-1, and the recess 114-2 is disposed at or abuts a side 104s3, opposite to the side 104s1, of the active region 104-1. In some embodiments, no recess is disposed at or abuts a side 104s2, extending between the side 104s1 and side 104s3, of the active region 104-1. In some embodiments, the side 104s2 of the active region 104 is free of facing a recess of the isolation structure 112 within a distance substantially equal to a distance between the recess 114-1 and the active region 104-1 along the X-direction. The recesses 114-1 and 114-2 are discontinuous or disconnected. The active region 104-1 has a length L₁, defined by the boundary of the isolation structure 112, along the Y-direction. The recess 114-1 (or 114-2) has a length L₂ along the Y-direction. In some embodiments, the length L₂ is greater than the length L₁. In some embodiments, the length L₂ is substantially the same as the length of the gate stack structure 130-1 (or the gate electrode of the gate stack structure 130-1) along the Y-direction.

In some embodiments, the semiconductor device 1a includes doped regions 121-1, 122-1, 122-2, 123-1, and 123-2 as well as a body region 124-1 within the substrate 102 (or active region 104-1). It should be noted that the semiconductor device 1a can include other doped regions (or well regions) to control, adjust, and/or modify electrical properties.

In some embodiments, the doped region 121-1 is disposed between the gate stack structures 130-1 and 130-2. In some embodiments, the doped region 121-1 is disposed within the body region 124-1. In some embodiments, the doped region 121-1 is configured to function as, for example, a source feature (or common source). The doped region 121-1 has a first conductive type. In some embodiments, the first conductive type is an n type. In some embodiments, n type dopants include arsenic (As), phosphorus (P), other group V elements, or any combination thereof.

The doped region 122-1 and the doped region 121-1 are disposed on two opposite sides of the gate stack structure 130-1. In some embodiments, the doped region 122-1 has the first conductive type. In some embodiments, the doped region 122-1 is configured to function as, for example, a drain feature.

The doped region 122-2 and the doped region 121-1 are disposed on two opposite sides of the gate stack structure 130-2. In some embodiments, the doped region 122-2 has the first conductive type. In some embodiments, the doped region 122-2 is configured to function as, for example, a drain feature.

The doped region 123-1 is disposed between the doped regions 121-1 and 122-1. The doped region 123-1 has the first conductive type and a dopant concentration less than that of the doped region 122-1. In some embodiments, the doped region 123-1 is configured to define a drift region between the channel region (not annotated) and the doped region 122-1.

The doped region 123-2 is disposed between the doped regions 121-1 and 122-2. The doped region 123-2 has the first conductive type and a dopant concentration less than that of the doped region 122-2. In some embodiments, the doped region 123-2 is configured to define a drift region between the channel region (not annotated) and the doped region 122-2. In some embodiments, each of the doped regions 123-1 and 123-2 is a lightly doped drain (LDD).

The body region 124-1 is disposed between the gate stack structures 130-1 and 130-2. The body region 124-1 is configured to control and/or modify the threshold voltage of the semiconductor device 1a. In some embodiments, a portion of the body region 124-1 overlaps the gate stack structure 130-1 (or 130-2) along the Z direction. The doped region 124-1 has a second conductive type different from the first conductive type. In some embodiments, the second conductive type is a p type. In some embodiments, p type dopants include boron (B), other group III elements, or any combination thereof.

The gate stack structures 130-1 and 130-2 are disposed on the substrate 102. In some embodiments, the gate stack structure 130-1 includes a gate dielectric layer 131-1 and a gate electrode 132-1. The gate stack structure 130-2 includes a gate dielectric layer 131-2 and a gate electrode 132-2. Each of the gate dielectric layers 131-1 and 131-2 may have a single layer or a multi-layer structure. In some embodiments, each of the gate dielectric layers 131-1 and 131-2 is a multi-layer structure that includes an interfacial layer and a high-k (dielectric constant greater than 4) dielectric layer. The interfacial layer can include dielectric material such as silicon oxide, silicon nitride, silicon oxynitride, other dielectric material, or a combination thereof. The high-k dielectric layer can include high-k dielectric material such as HfO₂, HfSiO, HfSiON, HfTaO, HfTIO, HfZrO, other suitable high-k dielectric materials, or a combination thereof. In some embodiments, the high-k dielectric material can further be selected from metal oxides, metal nitrides, metal silicates, transition metal-oxides, transition metal-nitrides, transition-metal silicates, metal oxynitrides, metal aluminates, and combinations thereof.

The gate electrode 132-1 is disposed on the gate dielectric layer 131-1. The gate electrode 132-2 is disposed on the gate dielectric layer 131-2. Each of the gate electrodes 132-1 and 132-2 includes polysilicon, silicon-germanium, and at least one metallic material including elements and compounds such as Mo, Cu, W, Ti, Ta, TiN, TaN, NiSi, CoSi, or other suitable conductive materials known in the art. In some embodiments, each of the gate electrodes 132-1 and 132-2 includes a work function metal layer that provides a metal gate with an n type-metal work function or p type-metal work function. The p type-metal work function materials include materials such as ruthenium, palladium, platinum, cobalt, nickel, conductive metal oxide, or other suitable materials. The n type-metal work function materials include materials such as hafnium zirconium, titanium, tantalum, aluminum, metal carbides (e.g., hafnium carbide, zirconium carbide, titanium carbide, and aluminum carbide), aluminides, or other suitable materials.

In some embodiments, the semiconductor device 1a has an etching stop layer 142. The etching stop layer 142 is disposed on the substrate 102. In some embodiments, the etching stop layer 142 is conformally disposed on the isolation structure 112. In some embodiments, the etching stop layer 142 is conformally disposed within the recesses 114-1 and has a curved profile at the location corresponding to the recess 114-1. In some embodiments, the etching stop layer 142 is conformally disposed within the recess 114-2 and has a curved profile at the location corresponding to the recess 114-2. The etching stop layer 142 includes dielectric materials, such as silicon oxide, silicon nitride, silicon oxynitride, or other dielectric materials.

In some embodiments, the semiconductor device 1a has an interlayer dielectric (ILD) 144. The ILD 144 covers the gate stack structures 130-1 and 130-2. The ILD 144 is disposed on and covers the etching stop layer 142. The ILD 144 includes silicon oxide, carbon-containing oxide such as silicon oxycarbide (SiOC), silicate glass, tetraethylorthosilicate (TEOS) oxide, un-doped silicate glass, or doped silicon oxide such as borophosphosilicate glass (BPSG), fluorine-doped silica glass (FSG), phosphosilicate glass (PSG), boron doped silicon glass (BSG), combinations thereof and/or other suitable dielectric materials. In some embodiments, the ILD 144 may include low-k dielectric material with a dielectric constant lower than 4, or extreme low-k (ELK) dielectric material with a dielectric constant lower than 2.5. In some embodiments, the low-k material includes a polymer based material, such as benzocyclobutene (BCB); or a silicon dioxide based material, such as hydrogen silsesquioxane (HSQ) or SiOF. The ILD 144 may be a single layer structure or a multi-layer structure.

In some embodiments, the ILD 144 has a protruding portion 144p1 over the isolation structure 112. In some embodiments, the protruding portion 144p1 fills the recesses 114-1 and protrudes toward the substrate 102. In some embodiments, the ILD 144 has a protruding portion 144p2 over the isolation structure 112. In some embodiments, the protruding portion 144p2 fills the recess 114-2 and protrudes toward the substrate 102. Although not shown in FIG. 1A, it should be notated that the length of the protruding portion 144p1 (or protruding portion 144p2) along the Y-direction is substantially the same as the length L₂ of the recesses 114-1.

In some embodiments, the semiconductor device 1a has conductive contacts 150-1, 150-2, 152-1, 154-1, and 154-2. The conductive contacts 150-1, 150-2, 152-1, 154-1, and 154-2 are disposed on the substrate 102 and embedded within the ILD 144. The conductive contact 150-1 is disposed on and/or electrically connected to the gate electrode 132-1. The conductive contact 150-2 is disposed on and/or electrically connected to the gate electrode 132-2. The conductive contact 152-1 is disposed on and/or electrically connected to the doped region 121-1. The conductive contact 154-1 is disposed on and/or electrically connected to the doped region 122-1. The conductive contact 154-2 is disposed on and/or electrically connected to the doped region 122-2. The conductive contacts 150-1, 150-2, 152-1, 154-1, and 154-2 include a conductive material, such as copper (Cu), titanium (Ti), tungsten (W), silver (Ag), aluminum (Al), titanium aluminum alloy (TiAl), titanium aluminum nitride (TiAIN), tantalum carbide (TaC), tantalum carbon nitride (TaCN), tantalum silicon nitride (TaSiN), manganese (Mn), zirconium (Zr), titanium nitride (TiN), tungsten nitride (WN), tantalum nitride (TaN), ruthenium (Ru) or a combination thereof.

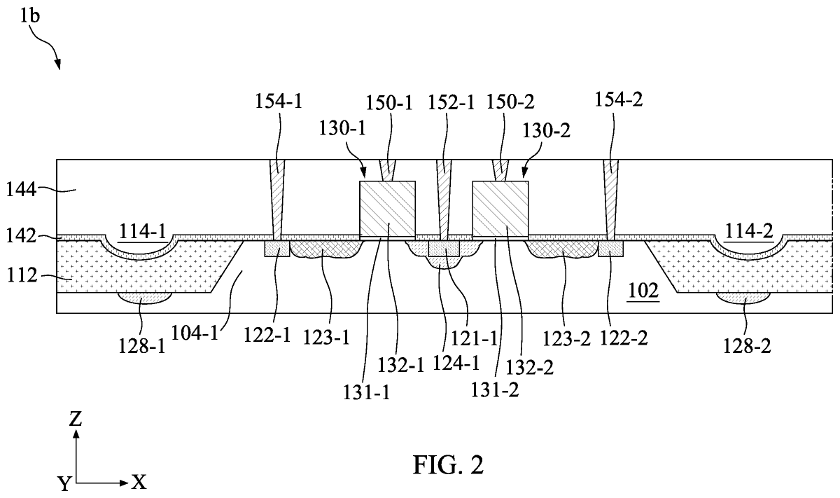

FIG. 2 illustrates a cross-sectional view of a semiconductor device 1b, in accordance with some embodiments of the present disclosure. The semiconductor device 1b is similar to the semiconductor device 1a as shown in FIG. 1B, with differences therebetween as follows.

In some embodiments, the semiconductor device 1b includes doped regions 128-1 and 128-2 (or impurity region). In some embodiments, the doped region 128-1 is located directly below the recess 114-1 (or protruding portion 144p1). In some embodiments, the doped region 128-2 is located directly below the recess 114-2 (or protruding portion 144p2). Each of the doped regions 128-1 and 128-2 has the second conductive type. The doped regions 128-1 and 128-2 are formed at the stage configured to form the body region 124-1, and thus have substantially the same dopant concentration and/or type of dopants as that of the body region 124-1.

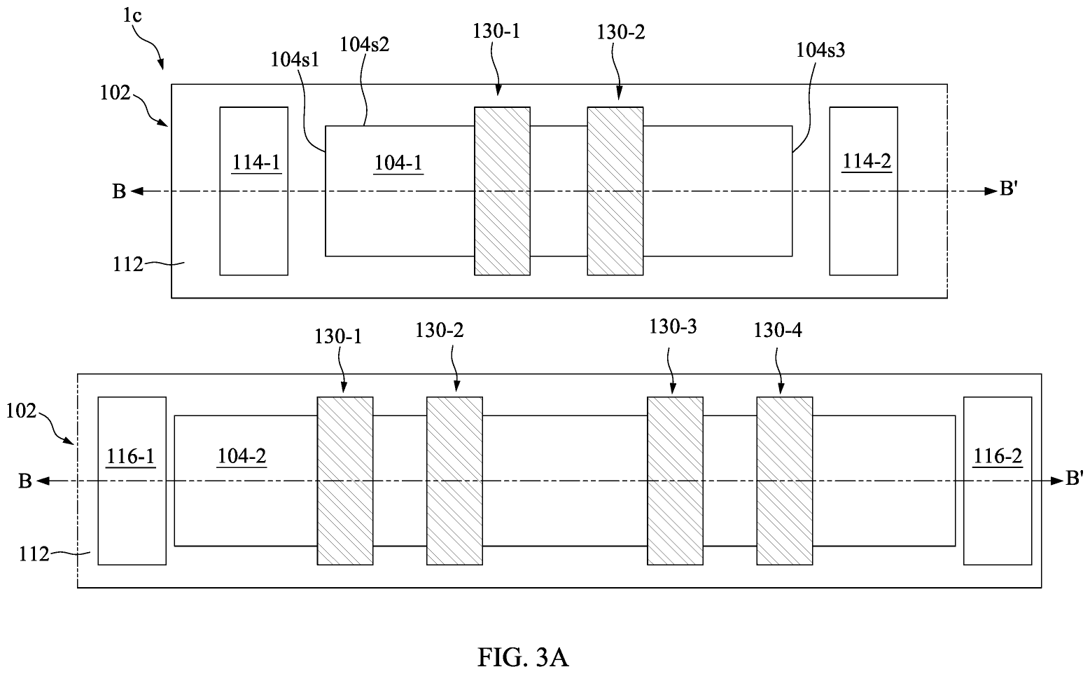

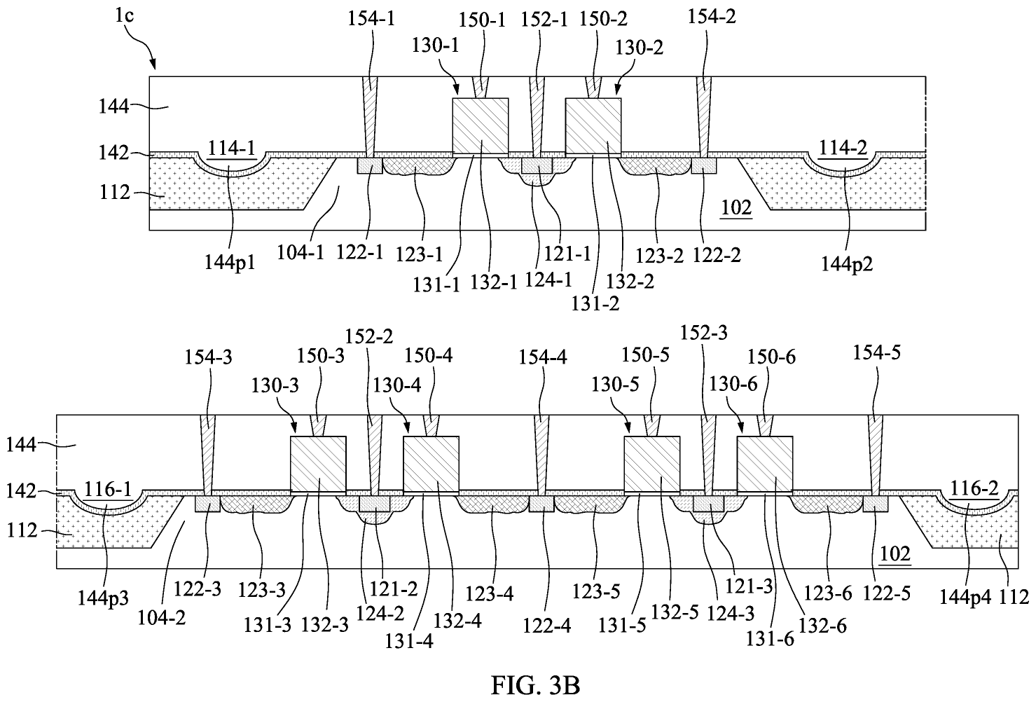

FIG. 3A and FIG. 3B illustrate a semiconductor device 1c, wherein FIG. 3A is a top view, and FIG. 3B is a cross-sectional view taken along line B-B′ of FIG. 1A. The semiconductor device 1c is similar to the semiconductor device 1a, with differences therebetween as follows.

Referring to FIG. 3A, the semiconductor device 1c further includes an active region 104-2. The active region 104-2 is configured to define a four-finger gate stack structure system. The semiconductor device 1c includes gate stack structures 130-3, 130-4, 130-5, and 130-6, each of which extending along the Y-direction and are arranged along the X-direction.

Referring to FIG. 3B, the isolation structure 112 defines recesses 116-1 and 116-2. In some embodiments, each of the recesses 116-1 and 116-2 is recessed from an upper surface of the isolation structure 112. For example, each of the recesses 116-1 and 116-2 has a bowl-shaped profile in a cross-sectional view. Each of the recesses 116-1 and 116-2 is formed by an etching technique configured to pattern a gate dielectric material, which will be described in detail later.

In some embodiments, the semiconductor device 1c includes doped regions 121-2, 121-3, 122-3, 122-4, 122-5, 123-3, 123-4, 123-5, and 123-6 as well as body regions 124-2, and 124-3 within the substrate 102 (or active region 104-2).

The doped region 121-2 is disposed between the gate stack structures 130-3 and 130-4. The doped region 121-3 is disposed between the gate stack structures 130-5 and 130-6. In some embodiments, each of the doped regions 121-2 and 121-3 is configured to function as, for example, a source feature (or common source). Each of the doped regions 121-2 and 121-3 has the first conductive type, such as an n type.

The doped regions 122-3 and 121-2 are disposed on two opposite sides of the gate stack structure 130-3. The doped region 122-4 is disposed between the gate stack structures 130-4 and 130-5. The doped regions 122-5 and 121-3 are disposed on two opposite sides of the gate stack structure 130-6. In some embodiments, the doped regions 122-3 to 122-5 have the first conductive type. In some embodiments, each of the doped region 122-3 to 122-5 is configured to function as, for example, a drain feature.

The doped region 123-3 is disposed between the doped regions 121-2 and 122-3. The doped region 123-4 is disposed between the doped regions 121-2 and 122-4. The doped region 123-5 is disposed between the doped regions 121-3 and 122-4. The doped region 123-6 is disposed between the doped regions 121-3 and 122-5. Each of the doped regions 123-3 to 123-6 has the first conductive type and a dopant concentration less than that of the doped region 122-3. In some embodiments, each of the doped regions 123-3 to 123-6 is configured to define a drift region.

The body region 124-2 is disposed between the gate stack structures 130-3 and 130-4. In some embodiments, a portion of the body region 124-2 overlaps the gate stack structure 130-3 (or 130-4) along the Z direction. The body region 124-3 is disposed between the gate stack structures 130-5 and 130-6. In some embodiments, a portion of the body region 124-3 overlaps the gate stack structure 130-5 (or 130-6) along the Z direction. Each of the body regions 124-2 and 124-3 has the second conductive type, such as a p type.

Each of the gate stack structures 130-3 to 130-6 is disposed on the substrate 102. The gate stack structure 130-3 includes a gate dielectric layer 131-3 and a gate electrode 132-3 disposed on the gate dielectric layer 131-3. The gate stack structure 130-4 includes a gate dielectric layer 131-4 and a gate electrode 132-4 disposed on the gate dielectric layer 131-4. The gate stack structure 130-5 includes a gate dielectric layer 131-5 and a gate electrode 132-5 disposed on the gate dielectric layer 131-5. The gate stack structure 130-6 includes a gate dielectric layer 131-6 and a gate electrode 132-6 disposed on the gate dielectric layer 131-6. The gate dielectric layers 131-3 to 131-6 have a material the same as or similar to that of the gate dielectric layer 131-1. The gate electrodes 132-3 to 132-6 have a material the same as or similar to that of the gate electrode 132-1.

In some embodiments, the etching stop layer 142 covers the isolation structure 112 and the substrate 102. The etching stop layer 142 covers the active region 104-1 and the active region 104-2. In some embodiments, the etching stop layer 142 is conformally disposed within the recesses 116-1 and has a curved profile at the location corresponding to the recess 116-1. In some embodiments, the etching stop layer 142 is conformally disposed within the recess 116-2 and has a curved profile at the location corresponding to the recess 116-2.

In some embodiments, the ILD 144 covers the gate stack structure 130-3 and 130-6. In some embodiments, the ILD 144 has a protruding portion 144p3 over the isolation structure 112. In some embodiments, the protruding portion 144p3 fills the recesses 116-1 and protrudes toward the substrate 102. In some embodiments, the ILD 144 has a protruding portion 144p4 over the isolation structure 112. In some embodiments, the protruding portion 144p4 fills the recess 116-2 and protrudes toward the substrate 102.

In some embodiments, the semiconductor device 1c includes conductive contacts 150-3, 150-4, 150-5, and 150-6. The conductive contact 150-3 is disposed on and/or electrically connected to the gate electrode 132-3. The conductive contact 150-4 is disposed on and/or electrically connected to the gate electrode 132-4. The conductive contact 150-5 is disposed on and/or electrically connected to the gate electrode 132-5. The conductive contact 150-6 is disposed on and/or electrically connected to the gate electrode 132-6. In some embodiments, the semiconductor device 1c includes conductive contacts 152-2 and 152-3. The conductive contact 152-2 is disposed on and/or electrically connected to the doped region 121-2. The conductive contact 152-3 is disposed on and/or electrically connected to the doped region 121-3. In some embodiments, the semiconductor device 1c includes conductive contacts 154-3, 154-4, and 154-5. The conductive contact 154-3 is disposed on and/or electrically connected to the doped region 122-3. The conductive contact 154-4 is disposed on and/or electrically connected to the doped region 122-4. The conductive contact 154-5 is disposed on and/or electrically connected to the doped region 122-5.

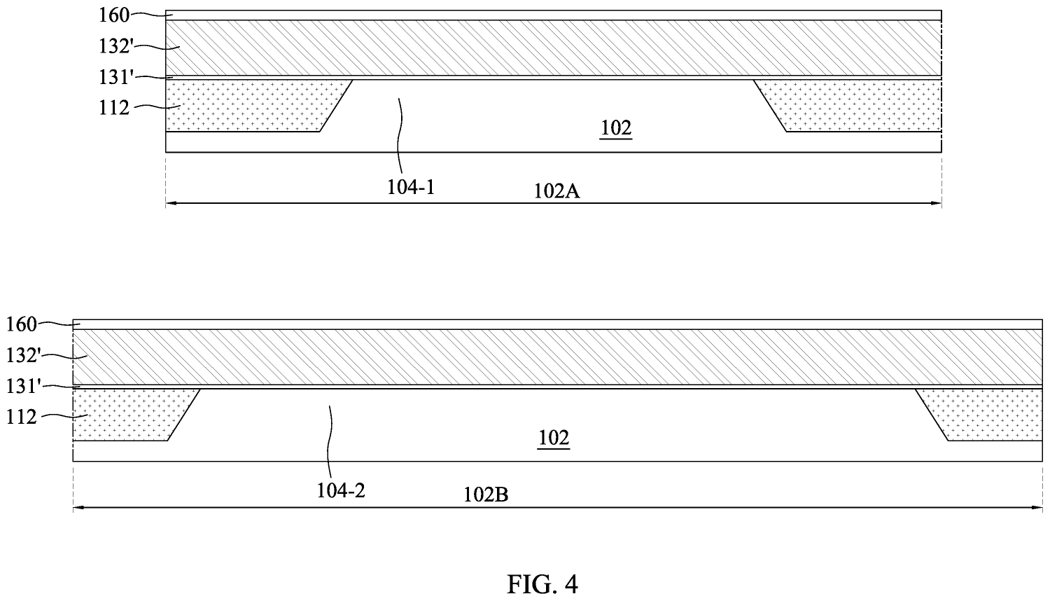

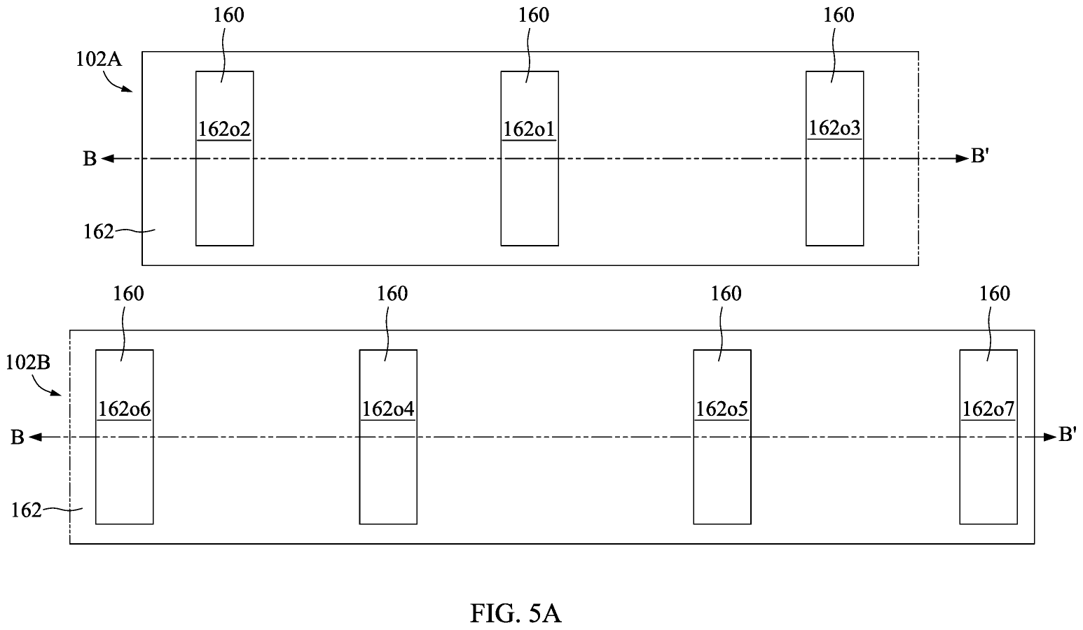

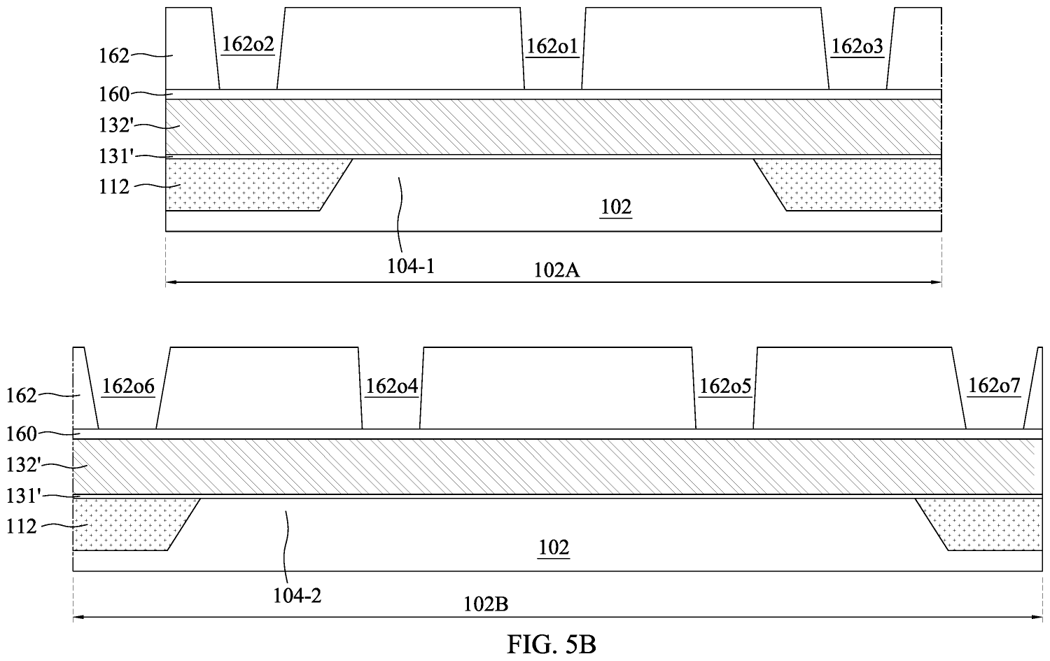

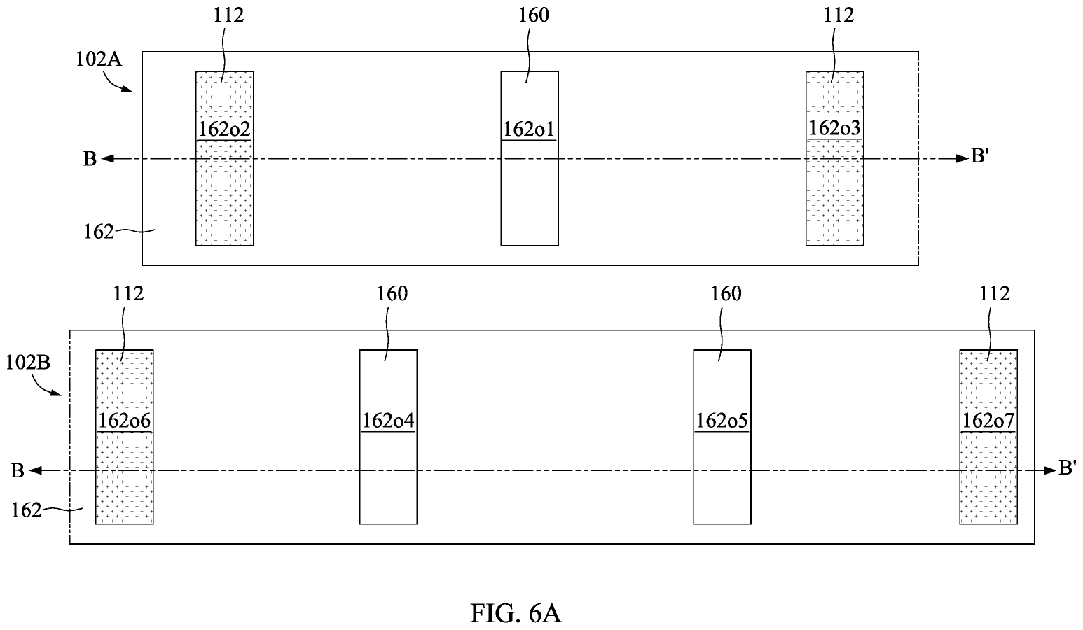

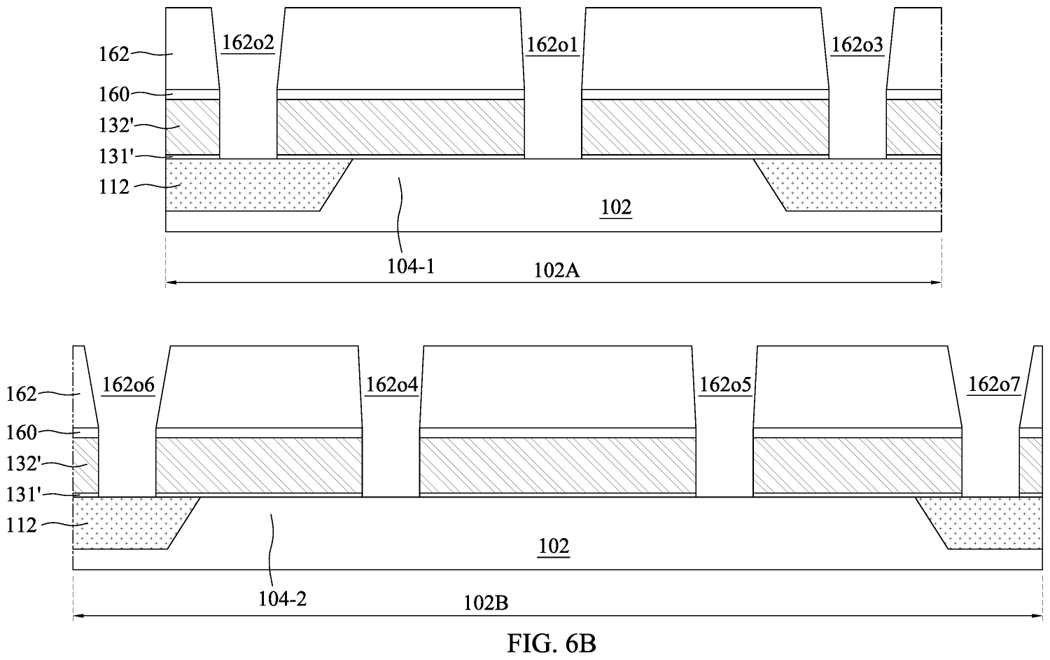

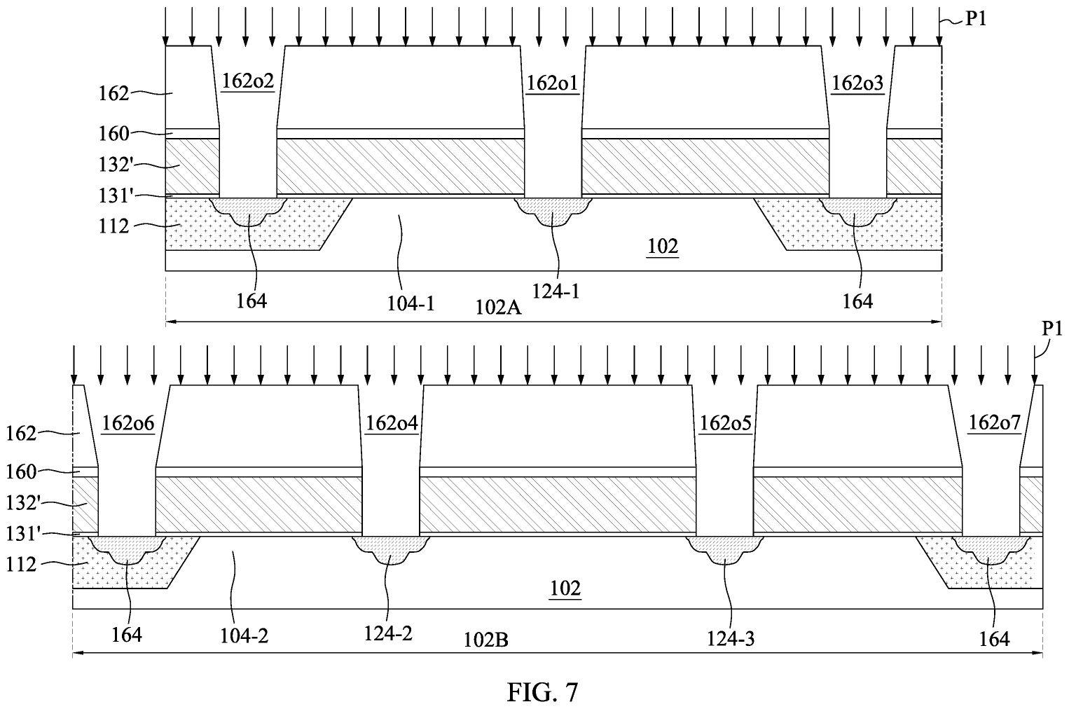

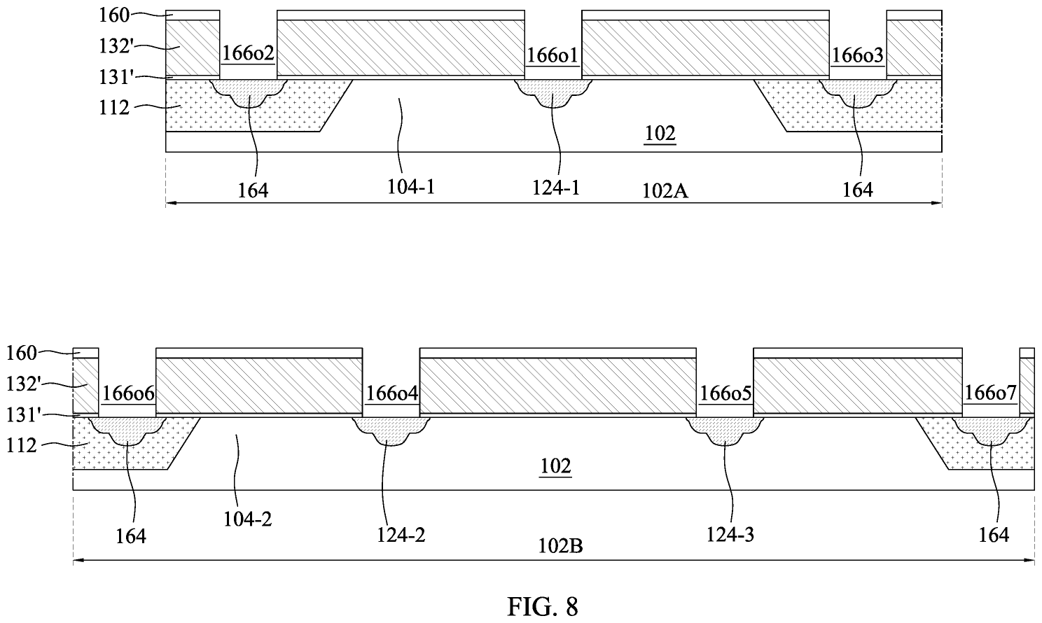

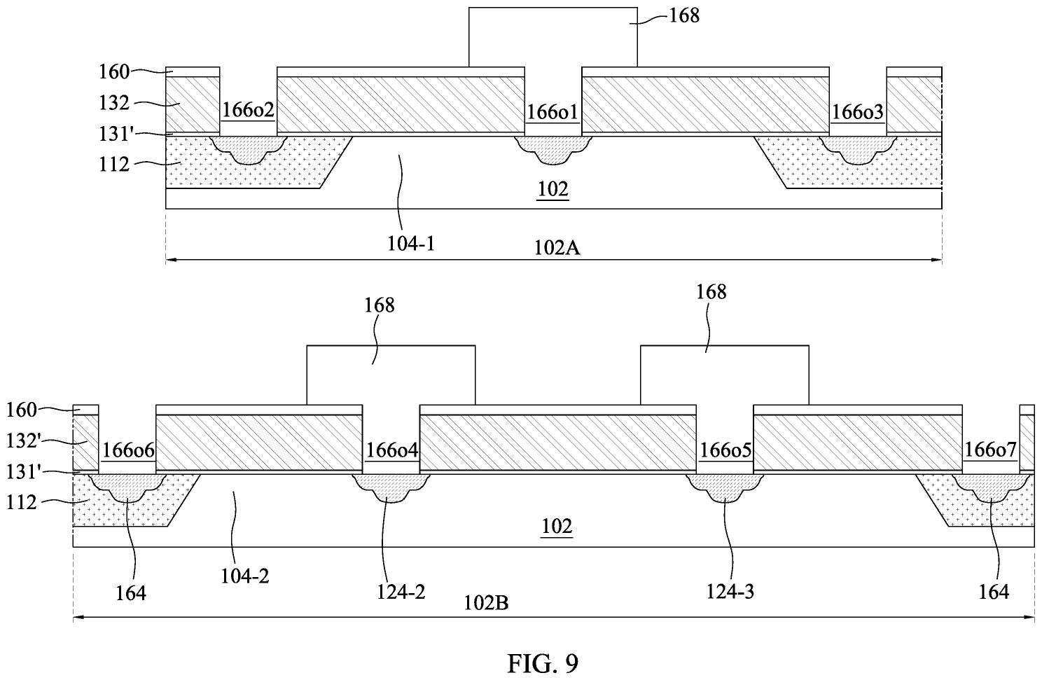

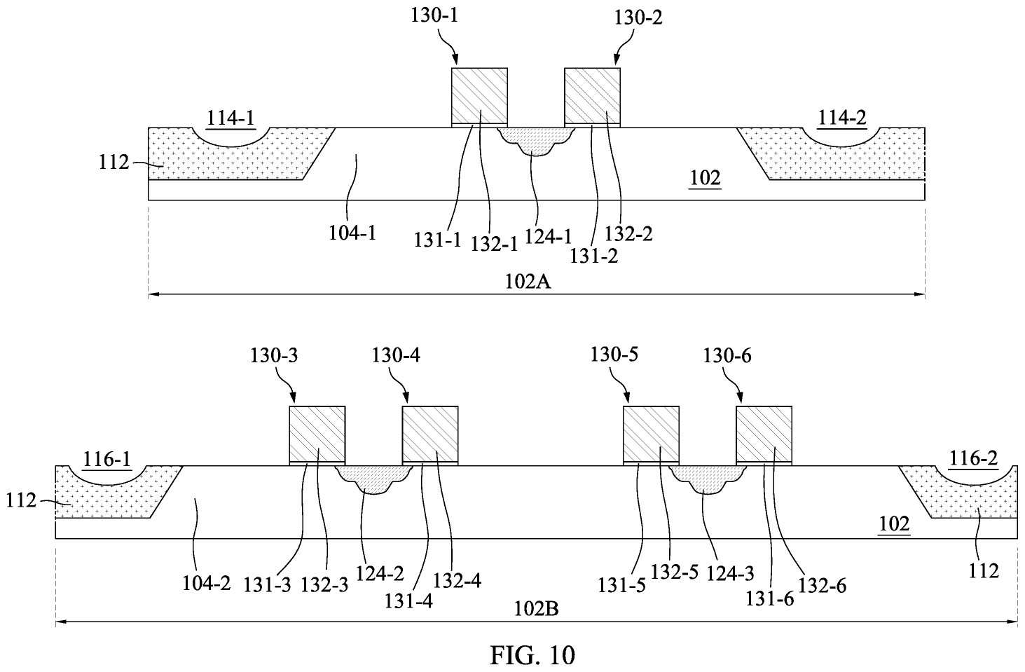

FIG. 4, FIG. 5A, FIG. 5B, FIG. 6A, FIG. 6B, FIG. 7, FIG. 8, FIG. 9, FIG. 10, and FIG. 11 illustrate various stages of manufacturing a semiconductor device (e.g., the semiconductor device 1c as shown in FIG. 3A and FIG. 3B), in accordance with some embodiments of the present disclosure. FIG. 4, FIG. 5B, FIG. 6B, and FIG. 7 to FIG. 11 are cross-sectional views, and FIG. 5A and FIG. 6A are top views of FIG. 5B and FIG. 6B, respectively.

Referring to FIG. 4, the substrate 102 is provided. The substrate 102 includes regions 102A and 102B. The region 102A is configured to form a two-finger gate stack structure system. The region 102B is configured to form a four-finger gate stack structure system.

The isolation structure 112 is formed within the substrate 102. In some embodiments, the isolation structure 112 includes a liner oxide (not shown), which may be a thermal oxide formed through a thermal oxidation of a surface layer of the substrate 102. The liner oxide may also be a deposited silicon oxide layer formed using, for example, atomic layer deposition (ALD), high-density plasma chemical vapor deposition (HDPCVD), chemical vapor deposition (CVD), or other suitable techniques. The isolation structure 112 may also include a dielectric material over the liner oxide, wherein the dielectric material may be formed using flowable chemical vapor deposition (FCVD), spin-on, or the like.

A gate dielectric material 131′ is formed on the substrate 102. The gate dielectric material 131′ will be patterned to define a gate dielectric layer in subsequent stages. In some embodiments, the gate dielectric material 131′ is formed by ALD, CVD, FCVD, or other suitable techniques.

A conductive layer 132′ (or gate electrode material) is formed on the gate dielectric material 131′. The conductive layer 132′ will be patterned to define a gate electrode in subsequent stages. In some embodiments, the conductive layer 132′ is formed by CVD, HDPCVD, FCVD, ALD, or other suitable techniques.

A mask 160 is formed on the conductive layer 132′. In some embodiments, the mask 160 includes silicon nitride, silicon oxide, silicon carbo-nitride, or multi-layers thereof. The mask 160 is formed by CVD, HDPCVD, FCVD, ALD, or other suitable techniques.

Referring to FIG. 5A and FIG. 5B, a photosensitive layer 162 is formed to cover the mask 160. In some embodiments, the photosensitive layer 162 includes a positive-tone or negative-tone photoresist such as a polymer. The photosensitive layer 162 defines openings 162o1, 162o2, and 162o3 over the region 102A of the substrate 102. The photosensitive layer 162 defines openings 162o4, 162o5, 162o6, and 162o7 over the region 102B of the substrate 102. The opening 162o2 (or outer opening) has a profile (e.g., the slope of aperture) different from that of the opening 162o6 (or outer opening) due to loading effects. The opening 162o2 (or outer opening) has a profile (e.g., the slope of aperture) different from that of the opening 162o1 (or inner opening). The openings 162o1, 162o4, and 162o5 have profiles that are substantially the same or similar.

Referring to FIG. 6A and FIG. 6B, a portion of the gate dielectric material 131′, conductive layer 132′, and mask 160 are removed. A portion of the substrate 102 of the region 102A is exposed by the opening 162o1. A portion of the substrate 102 of the region 102B is exposed by the openings 162o4 and 162o5. A portion of the isolation structure 112 is exposed by the openings 162o1, 162o3, 162o6, and 162o7. In some embodiments, the formation of the openings 162o2, 162o3, 162o6, and 162o7 allows the openings 162o1, 162o4, and 162o5 to have profiles that are substantially the same or similar (e.g., the slope of aperture). Under the conditions where the openings 162o1, 162o3, 162o6, and 162o7 are not formed, the openings 162o1 and 162o4 (or 162o5) may have different profiles (e.g., the slope of aperture) due to loading effects.

Referring to FIG. 7, an ion implantation technique P1 is performed. The body regions 124-1, 124-2, and 124-3 are formed. In some embodiments, impurity regions 164 are formed adjacent to the upper surface of the isolation structure 112. In other embodiments, dopants may penetrate the isolation structure 112, which may form a doped region (e.g., the doped region 128) under the isolation structure 112 as shown in FIG. 2.

In this embodiment, the openings 162o1, 162o4, and 162o5 have profiles that are substantially the same or similar, which provide substantially the same environment for dopants passing through. As a result, the dopant concentration, dopant profile, and/or dopant distribution of the body regions 124-1, 124-2, and 124-3 are substantially the same. Under the conditions where the openings 162o1, 162o3, 162o6, and 162o7 are not formed, the dopant concentration, dopant profile, and/or dopant distribution of the body regions 124-1, 124-2, and 124-3 may have a relatively great variation, which causes a shift of threshold voltage between two-finger and four-finger (or more fingers) gate stack structure systems.

Referring to FIG. 8, the photosensitive layer 162 is removed. The gate dielectric material 131′, conductive layer 132′, and/or mask 160 defines openings 166o1, 166o2, 166o3, 166o4, 166o5, 166o6, and 166o7 corresponding to the opening 162o1 to 162o7.

Referring to FIG. 9, a photosensitive layer 168 is formed to fill the opening 166o1, 166o4, and 166o5. The opening 166o2, 166o3, 166o6, and 166o7 are exposed by the photosensitive layer 168.

Referring to FIG. 10, a portion of the gate dielectric material 131′ and the conductive layer 132′ are removed to form the gate stack structures 130-1 to 130-6. The mask 160 and the photosensitive layer 168 are removed. In some embodiments, multiple etching techniques are performed to pattern the gate dielectric material 131′ and conductive layer 132′. For example, a first etching technique is performed to pattern the conductive layer 132′, and a second etching technique is performed to pattern the gate dielectric material 131′. In some embodiments, during the second etching technique, a portion of the isolation structure 112 exposed by the openings 166o2, 166o3, 166o6, and 166o7 is removed. As a result, the recesses 114-1, 114-2, 116-1, and 116-2 are formed. The locations of the recesses 114-1, 114-2, 116-1, and 116-2 correspond to the openings 162o2, 162o3, 162o6, and 162o7 of the photosensitive layer 162, which are configured to improve the shift of threshold voltage.

Referring to FIG. 11, the doped regions 121-1 to 121-3, 122-1 to 122-5, and 123-1 to 123-5 are formed within the substrate 102. The etching stop layer 142 and the ILD 144 are formed. Each of the etching stop layer 142 and the ILD 144 is formed by CVD, HDPCVD, or other suitable techniques. The ILD includes the protruding portions 144p1 to 144p4. The locations of the protruding portions 144p1 to 144p4 correspond to the openings 162o2, 162o3, 162o6, and 162o7 of the photosensitive layer 162, which are configured to improve the shift of threshold voltage. The conductive contacts 150-1 to 150-6, 152-1 to 152-3, and 154-1 to 154-5 are formed. Each of the conductive contacts 150-1 to 150-6, 152-1 to 152-3, and 154-1 to 154-5 is formed by physical vapor deposition (PVD), CVD, or other suitable techniques. As a result, a semiconductor device (e.g., the semiconductor device 1c as shown in FIG. 3A and FIG. 3B) is produced.

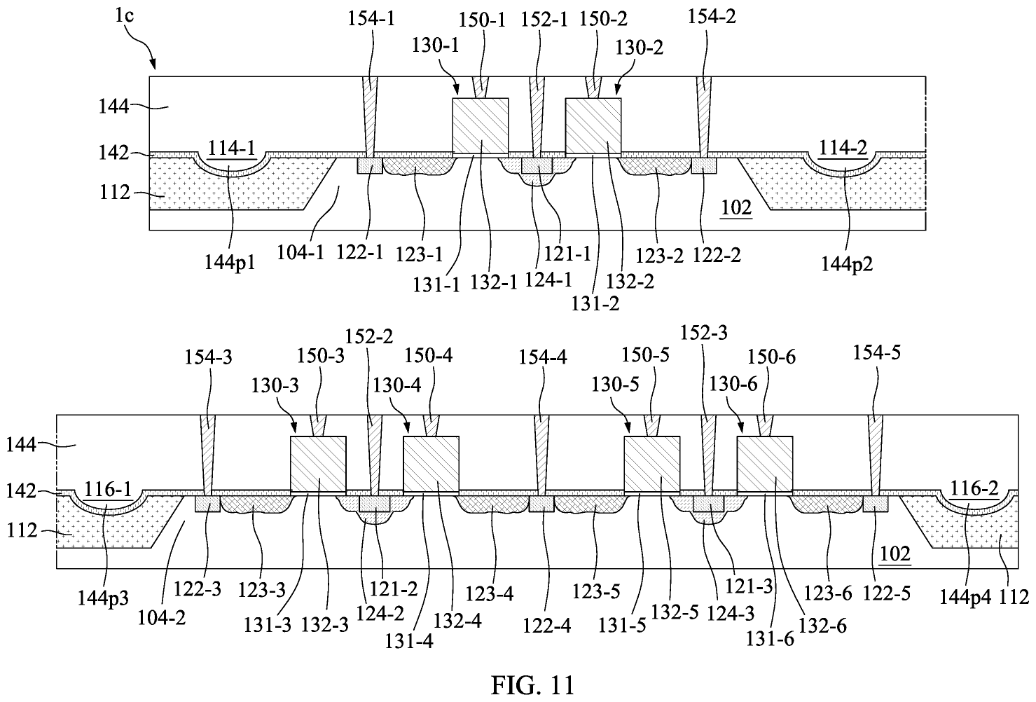

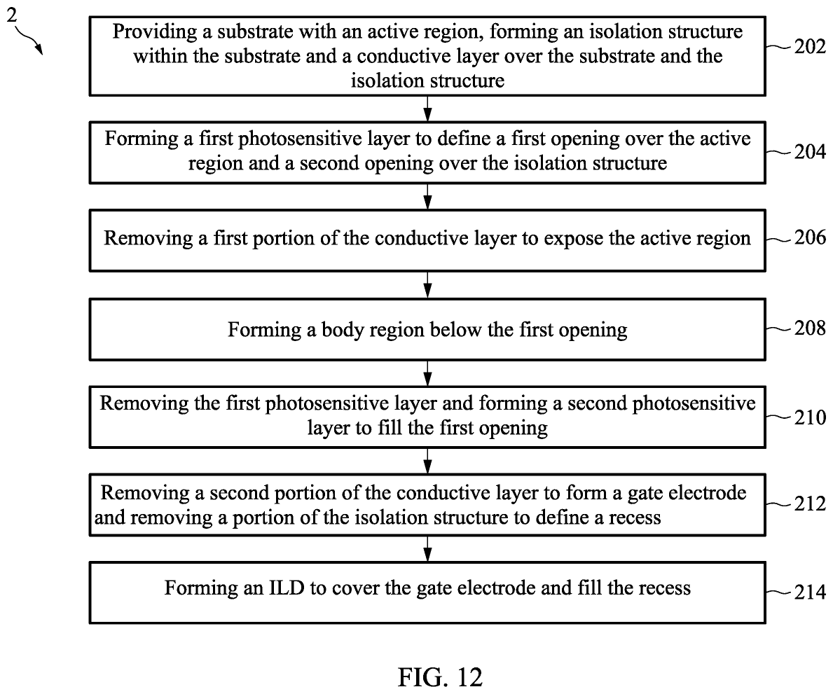

FIG. 12 is a flow chart illustrating a method 2 for manufacturing a semiconductor device according to various aspects of the present disclosure.

The method 2 begins with operation 202 in which a substrate is provided. An isolation structure is formed on the substrate to define an active region. A conductive layer is formed over the substrate and covering the isolation structure and the substrate.

The method 2 continues with operation 204 in which a first photosensitive layer is formed to cover the isolation structure and the substrate. The photosensitive layer is patterned to define a first opening over the active region and a second opening over the isolation structure.

The method 2 continues with operation 206 in which a first portion of the conductive layer, exposed by the first opening, is removed to expose the active region.

The method 2 continues with operation 208 in which dopants are implanted to the active region through the first opening to form a body region.

The method 2 continues with operation 210 in which the first photosensitive layer is removed, and a second photosensitive layer is formed to fill the first opening.

The method 2 continues with operation 212 in which a second portion of the conductive layer is removed to form a gate electrode and a portion of the isolation structure is removed to define a recess.

The method 2 continues with operation 214 in which an ILD is formed to cover the gate electrode and fill the recess.

Some embodiments of the present disclosure provide a semiconductor device. The semiconductor device includes a substrate, a plurality of gate stack structures, and an ILD. The substrate includes an active region. The gate stack structures are disposed on the active region of the substrate. The isolation structure is embedded within the substrate and surrounding the active region. The ILD covers the gate stack structures. The ILD includes a first protruding portion protruding toward the isolation structure.

Some embodiments of the present disclosure provide a semiconductor device. The semiconductor device includes a substrate, a plurality of gate stack structures, and an isolation structure. The substrate includes an active region. The gate stack structures are disposed on the active region of the substrate. The isolation structure is embedded within the substrate and surrounding the active region. The isolation structure defines a first recess recessed from an upper surface of the isolation structure.

Some embodiments of the present disclosure provide a method of manufacturing a semiconductor device. The method includes: providing a substrate comprising an active region surrounded by an isolation structure; forming a conductive layer over the active region and the isolation structure; removing a first portion of the conductive layer to form a first opening over the isolation structure and a second opening over the active region; forming a body region under the first opening; and removing a second portion of the conductive layer to form a plurality of gate electrodes over the active region.

The foregoing outlines structures of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate comprising an active region;
a plurality of gate stack structures disposed on the active region of the substrate;
an isolation structure embedded within the substrate and surrounding the active region; and
an interlayer dielectric (ILD) covering the plurality of gate stack structures, and the ILD comprises a first protruding portion protruding toward the isolation structure.

2. The semiconductor device of claim 1, wherein each of the plurality of gate stack structures extends along a first direction, and the first protruding portion of the ILD extends along the first direction.

3. The semiconductor device of claim 2, wherein a length of the active region is less than a length of the first protruding portion of the ILD along the first direction.

4. The semiconductor device of claim 3, wherein the length of the first protruding portion of the ILD is substantially equal to a length of one of the plurality of gate stack structures along the first direction.

5. The semiconductor device of claim 1, wherein the active region has a first side and a second side abutting the first side, the first side faces the first protruding portion of the ILD, and the second side is free from facing the first protruding portion of the ILD.

6. The semiconductor device of claim 5, wherein the active region has a third side opposite to the first side, and the ILD comprises a second protruding portion protruding toward the isolation structure and facing the third side of the active region.

7. The semiconductor device of claim 2, wherein the substrate comprises a body region with a first conductive type, and the semiconductor device further comprises a doped region with the first conductive type situated under the isolation structure.

8. The semiconductor device of claim 7, wherein the doped region overlaps the first protruding portion of the ILD along a second direction different from the first direction.

9. A semiconductor device, comprising:
a substrate comprising an active region;
a plurality of gate stack structures disposed on the active region of the substrate; and
an isolation structure embedded within the substrate and surrounding the active region, wherein the isolation structure defines a first recess recessed from an upper surface of the isolation structure.

10. The semiconductor device of claim 9, wherein each of the plurality of gate stack structures extends along a first direction, and the first recess extends along the first direction.

11. The semiconductor device of claim 10, wherein a length of the active region is less than a length of the first recess along the first direction.

12. The semiconductor device of claim 11, wherein the length of the first recess is substantially equal to a length of one of the plurality of gate stack structures along the first direction.

13. The semiconductor device of claim 9, wherein the active region has a first side and a second side abutting the first side, the first side faces the first recess, and the second side is free from facing the first recess.

14. The semiconductor device of claim 9, wherein the isolation structure defines a second recess, and the first recess and the second recess are disconnected.

15. The semiconductor device of claim 9, wherein the substrate comprises a body region with a first conductive type, and the semiconductor device further comprises an impurity region with the first conductive type situated under the isolation structure.

16. The semiconductor device of claim 15, wherein the impurity region overlaps the first recess.

17. The semiconductor device of claim 9, further comprising:
an interlayer dielectric (ILD) covering the gate stack structures and filling the first recess of the isolation structure.

18. A method of manufacturing a semiconductor device, comprising:
providing a substrate comprising an active region surrounded by an isolation structure;
forming a conductive layer over the active region and the isolation structure;
removing a first portion of the conductive layer to form a first opening over the isolation structure and a second opening over the active region;
forming a body region under the first opening; and
removing a second portion of the conductive layer to form a plurality of gate electrodes over the active region.

19. The method of claim 18, further comprising:
forming a doped region under the second opening.

20. The method of claim 18, further comprising:
removing a portion of the isolation structure exposed by the second opening to form a recess.
